(19) United States
(12) Patent Application Publication
(10) Pub. No.: US 2011/0287626 A1
(43) Pub. Date: Nov. 24, 2011

(54) OHMIC ELECTRODE AND METHOD OF FORMING THE SAME

(76) Inventors: Akinori Seki, Shizuoka-ken (JP); Masahiro Sugimoto, Aichi-ken (JP); Akira Kawahashi, Aichi-ken (JP); Yasuo Takahashi, Osaka-fu (JP); Masakatsu Maeda, Osaka-fu (JP)

(21) Appl. No.: 13/146,208

(22) PCT Filed: Jan. 29, 2010
(86) PCT No.: PCT/IB2010/000161

§ 371 Date: Jul. 26, 2011

(30) Foreign Application Priority Data
Jan. 30, 2009 (JP) 2009-020850

(51) Int. Cl. H01L 21/283

(52) U.S. Cl. 438/602; 257/E21.159

(57) ABSTRACT

The invention provides an ohmic electrode of a p-type SiC semiconductor element, which includes an ohmic electrode layer that is made of Ti₃SiC₂, and that is formed directly on a surface of a p-type SiC semiconductor. The invention also provides a method of forming an ohmic electrode of a p-type SiC semiconductor element. The ohmic electrode includes an ohmic electrode layer that is made of Ti₃SiC₂, and that is formed directly on a surface of a p-type SiC semiconductor. The method includes forming a ternary mixed film that includes Ti, Si, and C in a manner such that an atomic composition ratio, Ti:Si:C is 3:1:2, on a surface of a p-type SiC semiconductor to produce a laminated film; and annealing the produced laminated film under vacuum or under an inert gas atmosphere.

### BACKGROUND OF THE INVENTION

1. Field of the Invention

The invention relates to an ohmic electrode of a p-type SiC semiconductor element and a method of forming the same. More specifically, the invention relates to an ohmic electrode of a p-type SiC semiconductor element, which includes an ohmic electrode layer made of Ti₃SiC₂, which has improved surface smoothness, and which is formed directly on a p-type SiC semiconductor, and a method of forming the same.

2. Description of the Related Art

SiC single crystal is extremely stable thermally and chemically, has high mechanical strength, and is resistant to radiation. Further, as compared to Si (silicon) single crystal, the SiC signal crystal has excellent physical properties, such as high breakdown voltage, and high thermal conductivity. Further, it is easy to electronically control the conductivity type of the SiC single crystal to p-type conductivity or n-type conductivity by adding a dopant to the SiC single crystal. Also, the SiC single crystal has a wide band gap (4H-type SiC single crystal has a band gap of approximately 3.3 eV, and 6H-type SiC single crystal has a band gap of approximately 3.0 eV). Therefore, by using the SiC single crystal, it is possible to realize a high-temperature, high-frequency, high voltage, and environmentally-resistant semiconductor device that cannot be produced using other existing semiconductor materials such as Si single crystal and gallium arsenide (GaAs) single crystal. Thus, the SiC single crystal is expected to serve as a next-generation semiconductor material.

It is known that an electrode exhibiting a good ohmic characteristic, that is, an ohmic electrode is necessary to place the semiconductor device into practical use. The ohmic electrode exhibiting an ohmic characteristic is an electrode exhibiting a current-voltage characteristic in which current and voltage are linearly related to each other (that is, current and voltage are not non-linearly related to each other) regardless of a direction in which the current flows, and a magnitude of the voltage. The ohmic electrode has low resistance, and the current flows well in two directions in the ohmic electrode. However, a technology for stably forming the ohmic electrode on the p-type SiC semiconductor has not been established. Therefore, various proposals relating to development of the ohmic electrode of the p-type SiC semiconductor element have been made.

For example, Japanese Patent Application Publication No. 1-20616 (JP-A-1-20616) describes a method of forming a p-type SiC electrode, in which an ohmic electrode is formed by sequentially stacking Al and Si on p-type SiC single crystal, and then, performing anneal. In the method, the carrier concentration of the p-type SiC single crystal is equal to or higher than 1×10¹⁷/cm³, and an annealing temperature is 400 to 500° C.

Japanese Patent Application Publication No. 2003-86534 (JP-A-2003-86534) describes an ohmic electrode of an SiC semiconductor, and a method of producing the ohmic electrode of the SiC semiconductor. In the ohmic electrode, an electrode is connected to a first reaction layer that is formed on a p-type SiC semiconductor substrate by annealing. The first reaction layer includes a magnetic material, C, Si, and Al. The magnetic material and Si form an intermetallic compound. The method of producing the ohmic electrode of the SiC semiconductor includes a first step of stacking an Al film and an Ni film on a surface of a p-type SiC semiconductor substrate; a step of forming a first reaction layer by performing anneal under vacuum; and a step of connecting an electrode to the first reaction layer.

Japanese Patent Application Publication No. 2008-78434 (JP-A-2008-78434) describes a method of producing a semiconductor device that does not contain a by-product such as Al₄C₃, Ti₅Si₃C_{X}, or TiC. The method includes a first step of forming a Ti layer that is in contact with an SiC semiconductor layer; and a second step of forming an Al layer on the Ti layer by increasing a temperature of the SiC semiconductor layer and the Ti layer to a temperature higher than a first reference temperature at which Ti reacts with Al to form Al₃Ti, and lower than a second reference temperature at which Al₃Ti reacts with SiC to form Ti₃SiC₂. In the second step, SiC of the SiC semiconductor layer reacts with Al₃Ti to form Ti₃SiC₂, and thus, a Ti₃SiC₂ layer, which is in ohmic contact with the SiC semiconductor, is formed. However, the publication does not describe smoothness of a surface of the electrode after the anneal is performed.

Japanese Patent Application Publication No. 2008-78435 (JP-A-2008-78435) describes a method of producing a semiconductor device with low contact resistance, which does not contain a by-product such as Al₄C₃, Ti₅Si₃C_{X}, or TiC. The method includes a first step of forming a Ti layer that is in contact with an SiC semiconductor layer; a second step of forming an Al layer on the Ti layer; a third step of forming an Al₃Ti layer by annealing the SiC semiconductor layer, the Ti layer, and the Al layer at a temperature higher than a first reference temperature at which Ti reacts with Al to form Al₃Ti, and lower than a second reference temperature at which Al₃Ti reacts with SiC to form Ti₃SiC₂; and a fourth step of forming a Ti₃SiC₂ layer that is in ohmic contact with the SiC semiconductor layer by annealing the SiC semiconductor layer and the Al₃Ti layer at a temperature higher than the second reference temperature after completion of the reaction in which Ti reacts with Al to form Al₃Ti. However, a surface of the electrode is not smooth after the anneal is performed.

Further, Japanese Patent Application Publication No. 2008-227174 (JP-A-2008-227174) describes a method of forming an ohmic electrode on a p-type 4H—SiC substrate. The method includes a deposition step of sequentially depositing a first Al layer with a thickness of 1 to 60 nm, a Ti layer, and a second Al layer on a p-type 4H—SiC substrate; and an alloying step of forming an alloy layer made of the SiC substrate and the Ti layer, using the first Al layer, by performing anneal under a nonoxidizing atmosphere. However, a surface of the electrode is not smooth after the anneal is performed.

When forming the ohmic electrode of the p-type SiC semiconductor element in the above-described related art, a Deposition and Annealing (DA) method is used. In the DA method, an Al deposited film, which is normally unnecessary for a reaction for forming the Ti₃SiC₂ layer, and a Ti deposited film are formed and stacked, and then, anneal is performed at approximately 1000° C. In the anneal, an interface reaction occurs between SiC that is the semiconductor material, and Ti and Al deposited on SiC, and thus, the thin intermediate semiconductor layer, which is in contact with the SiC semiconductor, and which is made of Ti₃SiC₂, is formed.

According to the method of forming the electrode in the related art, it is difficult to form the intermediate semiconductor layer made of Ti₃SiC₂, whose thickness is uniform in the entire electrode on the SiC semiconductor. Compounds, such as Al₄C₃, Ti₅Si₃C_{X}, TiC, and Al₃Ti, are generated as by-products at the interface. The interface region, in which the by-products exist, has high contact resistance. Therefore, it is difficult to obtain good ohmic resistance by reducing the contact resistance of the electrode on the SiC semiconductor. Also, an alloy reaction occurs between Al and SiC, and SiC is unevenly eroded, and as a result, the surface of the electrode is made rough. Accordingly, it is difficult to connect a line and to bond a wire, which extends to the outside, to the electrode. A method, in which a semiconductor region directly under the electrode is heavily doped to reduce the thickness of the Schottky barrier, is effective for forming the ohmic electrode with low resistance on the p-type SiC semiconductor, as in the case of the other p-type semiconductor with a wide band gap. However, in the DA method in the related art, because the interface reaction between the semiconductor substrate and the evaporated film is used, the heavily-doped semiconductor region directly under the electrode is consumed by the interface reaction. Accordingly, in the related art, the electrode has low smoothness, and a poor ohmic characteristic. When an anneal temperature is decreased, the level of smoothness is slightly improved. In this case, however, the interface reaction does not proceed, and an electrode with a poor ohmic characteristic and high contact resistance is produced.

### SUMMARY OF THE INVENTION

The invention provides an ohmic electrode of a p-type SiC semiconductor element, which includes an ohmic electrode layer that is made of Ti₃SiC₂, and that has high surface smoothness and a good ohmic characteristic. The invention also provides a method of forming an ohmic electrode of a p-type SiC semiconductor element, which includes an ohmic electrode layer that is made of Ti₃SiC₂, and that has high surface smoothness and a good ohmic characteristic.

The inventors have found through study as follows. It is necessary to cause a p-type SiC semiconductor to have an ohmic characteristic by reducing the Schottky barrier by forming a heterojunction structure using a thin Ti₃SiC₂ layer with a uniform thickness. In a process of forming an ohmic electrode according to the Deposition and Annealing (DA) method in related art, a chemical reaction at an interface between an SiC semiconductor and an evaporated film is required. Therefore, not only Ti but also Al needs to be evaporated to form Ti₃SiC₂. For example, Al suppresses a side reaction that generates a phase other than Ti₃SiC₂, and absorbs Si that is left after SiC reacts with Ti. As a result of the chemical reaction, Al melt is generated. Because wettability between the Al melt and the SiC semiconductor is poor (that is, a contact angle is larger than 90°) at a temperature equal to or lower than 1000° C., the Al melt agglutinates. Accordingly, the necessity of Al is eliminated by forming Ti₃SiC₂ directly on the SiC semiconductor using a reaction inside the evaporated film without using the interface reaction between the SiC semiconductor and Ti. As a result of further study, the inventors have completed the invention.

An aspect of the invention relates to an ohmic electrode of a p-type SiC semiconductor element. The ohmic electrode includes an ohmic electrode layer that is made of Ti₃SiC₂, and that is formed directly on a surface of a p-type SiC semiconductor.

In the above-described aspect, the ohmic electrode layer may contain no Al component. A thickness of the ohmic electrode layer may be equal to or smaller than 20 nm. The thickness of the ohmic electrode layer may be equal to or smaller than 10 nm.

Another aspect of the invention relates to a method of forming an ohmic electrode of a p-type SiC semiconductor element. The ohmic electrode includes an ohmic electrode layer that is made of Ti₃SiC₂, and that is formed directly on a surface of a p-type SiC semiconductor. The method includes forming a ternary mixed film that includes Ti, Si, and C in a manner such that an atomic composition ratio, Ti:Si:C is 3:1:2, on a surface of a p-type SiC semiconductor to produce a laminated film; and annealing the produced laminated film under vacuum or under an inert gas atmosphere.

In the above-described aspect, in forming the ternary mixed film, an evaporated ternary mixed film may be formed by a deposition method after the surface of the p-type SiC semiconductor is cleaned, in vacuum deposition equipment. A thickness of the evaporated ternary mixed film may be equal to or smaller than 300 nm. The thickness of the evaporated ternary mixed film may be equal to or larger than 5 nm, and equal to or smaller than 300 nm. The laminated film may be annealed at a temperature which is equal to or higher than 900° C., and at which a chemical reaction proceeds while the ternary mixed film is constantly maintained in a solid phase state. The laminated film may be annealed at 900° C. to 1000° C. The laminated film may be annealed for 5 minutes to 120 minutes. The laminated film may be annealed for 5 minutes to 30 minutes. A thickness of the ohmic electrode layer may be equal to or smaller than 20 nm. The thickness of the ohmic electrode layer may be equal to or smaller than 10 nm.

According to the above-described aspect, it is possible to form the ohmic electrode of the p-type SiC semiconductor element, which includes the ohmic electrode layer that is made of Ti₃SiC₂, and that has high surface smoothness and a good ohmic characteristic. Also, according to the above-described aspect, it is easy to form the ohmic electrode of the p-type SiC semiconductor element, which includes the ohmic electrode layer that is made of Ti₃SiC₂, and that has high surface smoothness and a good ohmic characteristic.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1 is a schematic diagram showing an evaporated film formed in a method of forming an ohmic electrode of a p-type SiC semiconductor element according to an embodiment of the invention;

FIG. 2 is a schematic diagram showing a laminated film formed in a method of forming an example of an ohmic electrode of a p-type SiC semiconductor element in related art;

FIG. 3 is a schematic diagram showing the method of forming the ohmic electrode of the p-type SiC semiconductor element according to the embodiment of the invention;

FIG. 4 is a schematic diagram showing the method of forming the ohmic electrode of the p-type SiC semiconductor element in related art;

FIG. 5 is a graph showing current-voltage characteristics of an ohmic electrode of a p-type SiC semiconductor element, which is produced in an example of the invention;

FIG. 6 is a graph showing results of measurement of current-voltage of an ohmic electrode of a p-type SiC semiconductor element, which is produced in a comparative example according to related art;

FIG. 7 is a schematic diagram showing an example of a field-effect transistor made of silicon carbide, to which the ohmic electrode of the p-type SiC semiconductor element according to the invention is applied;

FIG. 8 is a schematic diagram showing an example of a silicon carbide N-channel power field-effect transistor with a vertical structure, to which the ohmic electrode of the p-type SiC semiconductor element according to the invention is applied;

FIG. 9 is a schematic diagram showing an example of a silicon carbide N-channel insulated gate bipolar transistor with a vertical structure, to which the ohmic electrode of the p-type SiC semiconductor element according to the invention is applied; and

FIG. 10 is a copy of a Transmission Electron Microscope (TEM) photograph of a section of an electrode/SiC in a first comparative example after anneal is performed, the electrode being formed using Al/Ti according to a DA method.

### DETAILED DESCRIPTION OF EMBODIMENTS

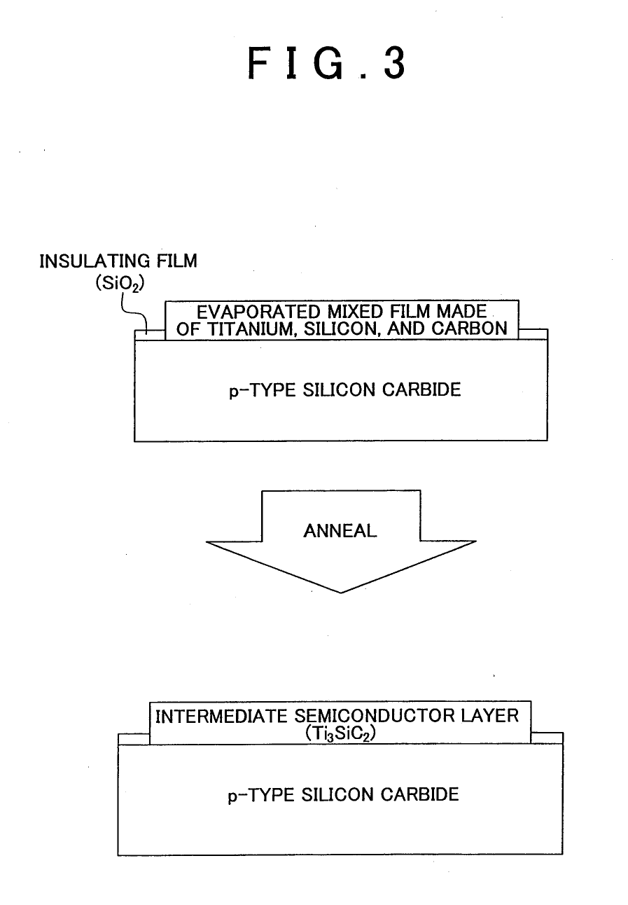

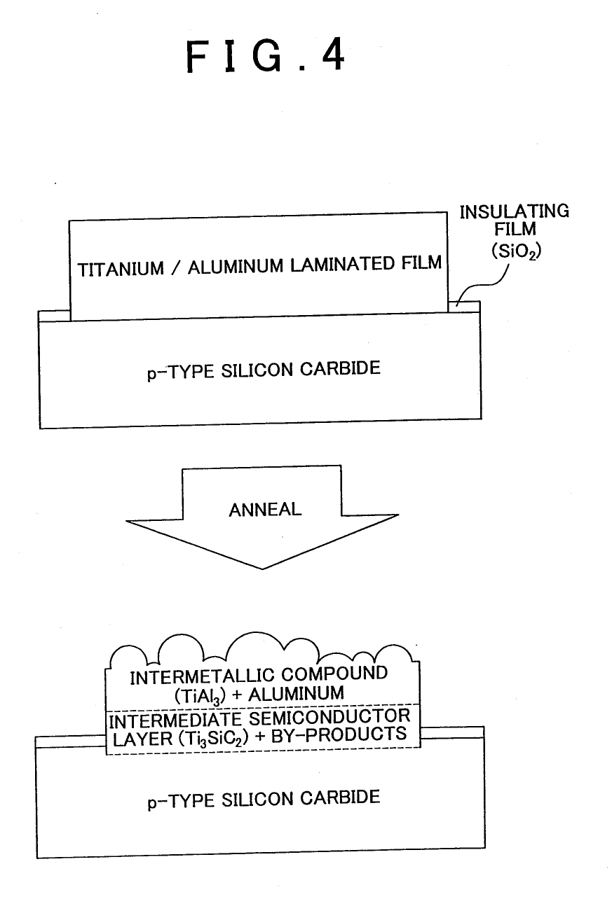

Hereinafter, an embodiment of the invention will be described in detail with reference to the drawings. An ohmic electrode of a p-type SiC semiconductor element according to the embodiment of the invention shown in FIG. 3 will be compared with an example of an ohmic electrode of a p-type SiC semiconductor element in related art shown in FIG. 4. In the ohmic electrode of the p-type SiC semiconductor element according to the embodiment of the invention, an intermediate semiconductor layer (i.e., an electrode) made of Ti₃SiC₂ does not contain an impurity, and a surface of the intermediate semiconductor layer has high smoothness. In contrast, in the ohmic electrode of the p-type SiC semiconductor element in related art, a mixed layer containing an intermetallic compound (TiAl₃) and a coagulation of Al is formed on an intermediate semiconductor layer containing Ti₃SiC₂ and by-products, and thus, a surface of the electrode has low smoothness.

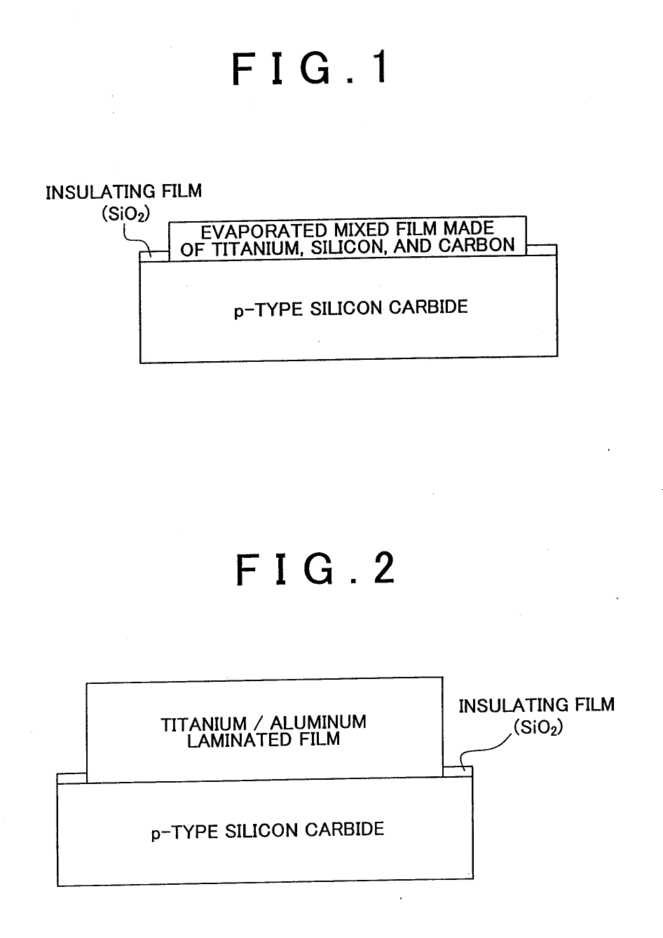

Further, as shown in FIG. 3 and FIG. 4, a method of forming the ohmic electrode of the p-type SiC semiconductor element according to the embodiment of the invention includes a step (a) of forming a ternary mixed film made of Ti, Si, and C (an atomic composition ratio, Ti:Si:C=3:1:2) on a surface of a p-type SiC semiconductor to produce a laminated film (refer to FIGS. 1 and 3); and a step (b) of annealing the produced laminated film to form an ohmic electrode layer made of Ti₃SiC₂ directly on the surface of the p-type SiC semiconductor. Thus, the ohmic electrode does not contain an impurity attributed to Al, and the surface of the electrode has high smoothness. In contrast, in a method of forming the ohmic electrode of the p-type SiC semiconductor element in related art, a Ti/Al laminated film is formed on a surface of a p-type SiC semiconductor (refer to FIGS. 2 and 4), and then, anneal is performed. The by-products, such as Al₄C₃, Ti₅Si₃C_{X}, and TiC, are formed in the ohmic electrode layer. The layer containing the intermetallic compound (TiAl₃) and the coagulation of Al is formed on the ohmic electrode layer made of Ti₃SiC₂. The intermetallic compound (TiAl₃) is a component containing Al. Thus, the layers have low surface smoothness, and it is considered that the ohmic characteristic of the ohmic electrode is decreased due to the low surface smoothness.

It is considered that the electrode according to the embodiment of the invention has high surface smoothness and a good ohmic characteristic for the following reason. In the method according to the embodiment of the invention, the ternary mixed film (i.e., the evaporated film) made of Ti, Si, and C (the composition ratio is 3:1:2) is formed on the cleaned surface of the SiC semiconductor, and anneal is performed. Thus, a chemical reaction proceeds while the film is constantly maintained in a solid phase state. Therefore, the reaction for forming Ti₃SiC₂ is completed without greatly changing a form. That is, the ohmic electrode is formed while substantially maintaining the smooth surface that is formed when evaporation is performed.

In the evaporated film, the composition of Ti, Si, and C is controlled to correspond to Ti₃SiC₂. The evaporated film is in the non-equilibrium three-phase coexisting state. Therefore, a driving force for the reaction inside the evaporated film is much higher than a driving force for a reaction between the stable SiC semiconductor and Ti. Thus, it is considered that the reaction proceeds inside the film while suppressing the interface reaction between the SiC semiconductor and Ti. In order to suppress the interface reaction between the SiC semiconductor and Ti, it is preferable to prevent the temperature of the film from being locally increased due to heat generated by the reaction inside the film. Because the extremely thin Ti₃SiC₂ layer needs to be formed, the thickness of the evaporated film is minimized. Thus, an amount of reaction heat is reduced. In addition, by using the fact that the SiC semiconductor has high thermal conductivity, the heat is effectively transferred from a portion of the film, at which the reaction proceeds. Thus, it is possible to prevent the temperature of the film from being locally increased.

SiC used to form the p-type SiC semiconductor is not particularly limited. Examples of SiC used to form the p-type SiC semiconductor include polytype SiC, such as 3C—SiC, 4H—SiC, and 6H—SiC. In the invention, SiC with any crystal structure may be used. It is preferable to use 4H—SiC. Because SiC is an extremely hard material, it is difficult to increase the degree of flatness of a cutout portion of SiC. If a metal electrode is press-fitted to the p-type SiC semiconductor substrate, the metal electrode is press-fitted to the p-type SiC semiconductor while a gap is left between the metal electrode and the p-type SiC semiconductor. Thus, it is difficult to obtain a junction with low resistance. Therefore, a method, in which an electrode component is evaporated on the p-type SiC semiconductor, is generally employed.

In the embodiment of the invention, in the step (a), the ternary mixed film made of Ti, Si, and C (the atomic composition ratio, Ti:Si:C=3:1:2) needs to be formed on the surface of the p-type SiC semiconductor. By forming the ternary mixed film made of Ti, Si, and C, it is possible to form the ohmic electrode layer made of Ti₃SiC₂ directly on the surface of the p-type SiC semiconductor, thereby obtaining the junction with low resistance in an anneal step (b) described later.

Examples of the method of forming the ternary mixed film made of Ti, Si, and C include the method in which the ternary mixed film made of Ti, Si, and C (the composition ratio (the atomic composition ratio) among Ti, Si, and C is 3:1:2) is formed on the surface of the SiC semiconductor substrate, which has been sufficiently cleansed and cleaned as shown in FIG. 3. The ternary mixed film is formed by performing evaporation. In the evaporation, given materials, which include the elements Ti, Si, and C in a manner such that the atomic composition ratio, Ti:Si:C is 3:1:2, are used as targets. For example, powder, lumps, or compacts of Ti, Si, and C (carbon), powder, lumps, or compacts of Ti, SiC, and C, powder, lumps, or compacts of Ti, Si, and TiC, or powder, lumps, or compacts of Ti₃SiC₂ are used as targets. The evaporation is performed using deposition equipment, for example, radio-frequency magnetron sputtering equipment, under a discharge atmosphere that is a rare gas atmosphere, for example, an Ar atmosphere, for example, at an output of 100 to 300 W, for example, at an output of 200 W in an Ar forward direction, for example, for 5 to 500 seconds, preferably 10 to 360 seconds. Ti₃SiC₂ is titanium silicon carbide that has characteristics of metal and ceramic materials. For example, the titanium silicon carbide is produced by methods described in Published Japanese Translation of PCT application No. 2003-517991, Japanese Patent Application Publication No. 2004-107152 (JP-A-2004-107152), and Japanese Patent Application Publication No. 2006-298762 (JP-A-2006-298762).

In the embodiment of the invention, in the above-described step (a), the ternary mixed film, which includes Ti, Si, and C in a manner such that the composition ratio (the atomic composition ratio) among Ti, Si, and C is 3:1:2, is formed on the p-type SiC semiconductor to produce a laminated film. The thickness of the ternary mixed film is preferably equal to or smaller than 300 nm, and more preferably equal to or larger than 5 nm, and equal to or smaller than 300 nm. More specifically, in the deposition equipment, after the surface of the p-type SiC semiconductor is cleaned, the evaporated ternary mixed film is formed by the vacuum deposition method. Then, in the step (b), the produced laminated film is annealed under vacuum or under an inert gas atmosphere. Thus, the ohmic electrode layer made of Ti₃SiC₂ is formed directly on the p-type semiconductor. In the step (b), it is preferable that the laminated film should be annealed at a temperature which is equal to or higher than 900° C., and at which the chemical reaction proceeds while the ternary mixed film is constantly maintained in the solid phase state during heating, preferably at 900° C. to 1000° C., for 5 minutes to 120 minutes, preferably 5 minutes to 30 minutes.

In the embodiment of the invention, by combining the step (a) and the step (b), it is possible to easily form the ohmic electrode of the p-type SiC semiconductor element, which includes the ohmic electrode layer that is made of Ti₃SiC₂, and that has high surface smoothness and a good ohmic characteristic.

In the embodiment of the invention, the intermediate semiconductor layer made of Ti₃SiC₂, which is thin and has a uniform thickness, is formed in the entire electrode portion so that the intermediate semiconductor layer is in contact with the SiC semiconductor substrate. In addition, it is possible to suppress a side reaction that generates, for example, Al₄C₃, Ti₅Si₃C_{X}, TiC, and Al₃Ti at the interface between the SiC semiconductor and the electrode portion. Thus, a heterojunction structure is formed on the SiC semiconductor, and thus, the ohmic electrode with a good ohmic characteristic is produced.

Hereinafter, a first example of the invention will be described. In the first example described below, a specimen was evaluated using a method described below. However, the measurement method described below is an exemplary method. The specimen may be evaluated using another similar device under a similar condition. A method, in which arithmetic average roughness (μm) is measured, was employed as the method of measuring the surface roughness of the electrode. The stylus-type surface roughness measuring device SE-40C (a detector model DR-30) manufactured by Kosaka Laboratory Ltd. was used as the measuring device for measuring the surface roughness of the electrode. A method, in which a current-voltage characteristic between electrodes is measured, was employed as the method of measuring the ohmic characteristic. The digital multimeter R6581 with high accuracy manufactured by Advantest Corporation was used as the measuring device for measuring the ohmic characteristic. Also, the power supply KX-100H manufactured by Takasago Ltd. was used as a constant voltage power supply.

### First Example

An evaporated film was formed using a semiconductor substrate made of p-type 4H—SiC. The semiconductor substrate made of p-type 4H—SiC had a thickness of 369 μm, resistivity of 75 to 2500 Ω cm, and a plane inclined from a plane (0001) by an off-angle of 8° toward a [11-20] direction. An electrode was to be formed on an Si surface of the semiconductor substrate. The evaporated film was formed under the condition described below. Radio-frequency magnetron sputtering equipment was used as deposition equipment. Powder, lumps, or compacts of Ti, Si, and C (the composition ratio (the atomic composition ratio), Ti:Si:C=3:1:2) were used as sputtering targets. The evaporation condition was as follows. Before the Ti—S—C film was deposited, the substrate was cleaned by an ordinary method. The evaporation was performed under the Ar discharge atmosphere, at the output of 200 W in the Ar forward direction, for a discharge time of 360 seconds. The evaporated ternary mixed film, which includes Ti, Si, and C (the composition ratio (the atomic composition ratio), Ti:Si:C=3:1:2), was formed on the surface of the semiconductor under the above-described condition, and thus, a laminated film, in which the evaporated ternary mixed film has the thickness of 300 nm, was produced. The surface roughness and the ohmic characteristic of the produced laminated film were evaluated. Table 1 shows a result of the evaluation of the surface roughness. FIG. 5 and Table 2 show results of the evaluation of the ohmic characteristic.

An ohmic electrode was formed by annealing the laminated film produced in the above-described step under the vacuum atmosphere (1 to 10×10⁻⁴ Pa), or under the Ar or N₂ atmosphere, at 1000° C. for 10 minutes or 15 minutes. The surface roughness and the ohmic characteristic of the produced ohmic electrode were evaluated. Table 1 shows a result of the evaluation of the surface roughness. FIG. 5 and Table 2 show results of the evaluation of the ohmic characteristic.

### First Comparative Example

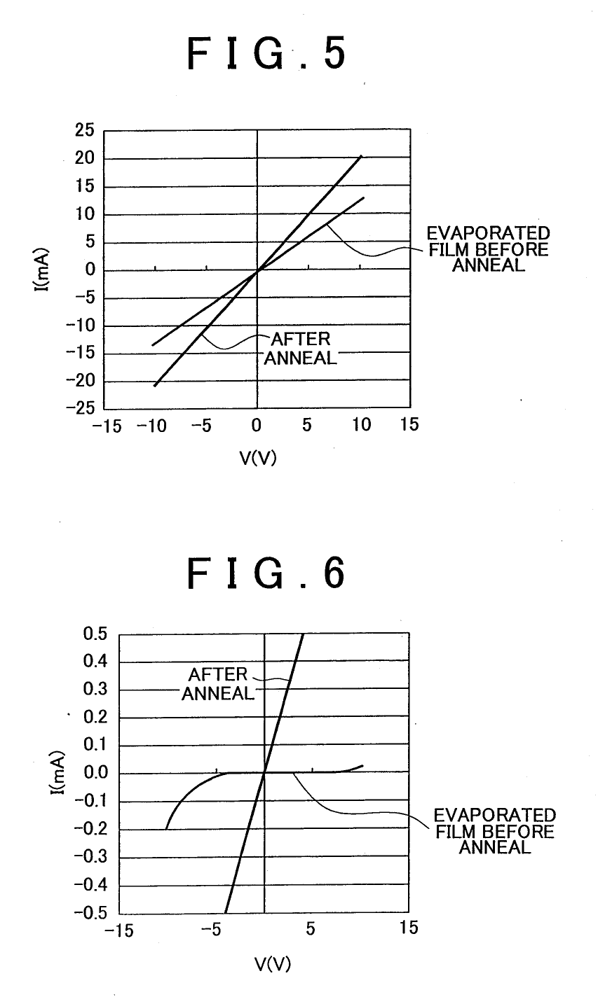

An evaporated film was formed using a semiconductor substrate made of p-type 4H—SiC. The semiconductor substrate made of p-type 4H—SiC had a thickness of 369 μm, resistivity of 75 to 2500 Ω cm, and a plane inclined from a plain (0001) by an off-angle of 8° toward a [11-20] direction. An electrode was to be formed on an Si surface of the semiconductor substrate. The evaporated film was formed under the condition described below. Electron beam deposition equipment was used as deposition equipment. Ti and Al were used as deposition materials. Ti (80 nm)/Al (375 nm) were deposited on the surface of the semiconductor under the above-described condition, and thus, a laminated film was produced. The surface roughness and the ohmic characteristic of the produced laminated film were evaluated. Table 1 shows a result of the evaluation of the surface roughness. FIG. 6 and Table 2 show results of the evaluation of the ohmic characteristic.

An ohmic electrode was formed by annealing the laminated film produced in the above-described step in the Ar or N₂ atmosphere (at the atmospheric pressure), at 1000° C. for 10 minutes. The surface roughness and the ohmic characteristic of the ohmic electrode were evaluated. Table 1 shows a result of the evaluation of the surface roughness. FIG. 6 and Table 2 show results of the evaluation of the ohmic characteristic.

TABLE 1

| | | Surface roughness (μm) | |
|---|---|---|---|
| | Evaporated film | Before anneal | After anneal |
| First example | TiSiC | 0.05 | 0.1 to 0.2 (1000° C. × |
| | | | 15 min) |
| First comparative | Ti/Al | 0.05 | 1.0 (1000° C. × 10 |
| example | | | min) |

TABLE 2

| | | I-V characteristic | |
|---|---|---|---|
| | Evaporated film | Before anneal | After anneal |
| First example | TiSiC | ohmic | low resistance |
| First comparative | Ti/Al | non-ohmic | ohmic |
| example | | | |

The evaluation results show that the ohmic electrode produced in the first example has high surface smoothness, and a good ohmic characteristic. The evaluation results also show that the laminated film in the first example, which was formed by evaporating the ternary mixed film on the semiconductor substrate material, has high surface smoothness and a good ohmic characteristic. The evaluation results also show that the ohmic characteristic was further improved by annealing. In contrast, the evaluation results show that the ohmic electrode produced in the first comparative example has an ohmic characteristic, but has low smoothness (refer also to a TEM photograph in FIG. 10). The evaluation results also show that the laminated film in the first comparative example, which was formed by depositing Ti/Al film on the semiconductor substrate material, has high smoothness, but does not have an ohmic characteristic. The evaluation results also show that the ohmic characteristic was obtained by annealing, but the level of smoothness was decreased by annealing in the first comparative example.

In the above-described example, the laminated film, in which the evaporated ternary mixed film had the thickness of 300 nm, was formed. However, the thickness of the evaporated ternary mixed film may be controlled to any value. Accordingly, the thickness of the Ti₃SiC₂ ohmic electrode layer may be controlled to, for example, a value equal to or smaller than 20 nm, for example, a value equal to or smaller than 10 nm.

### Second Example

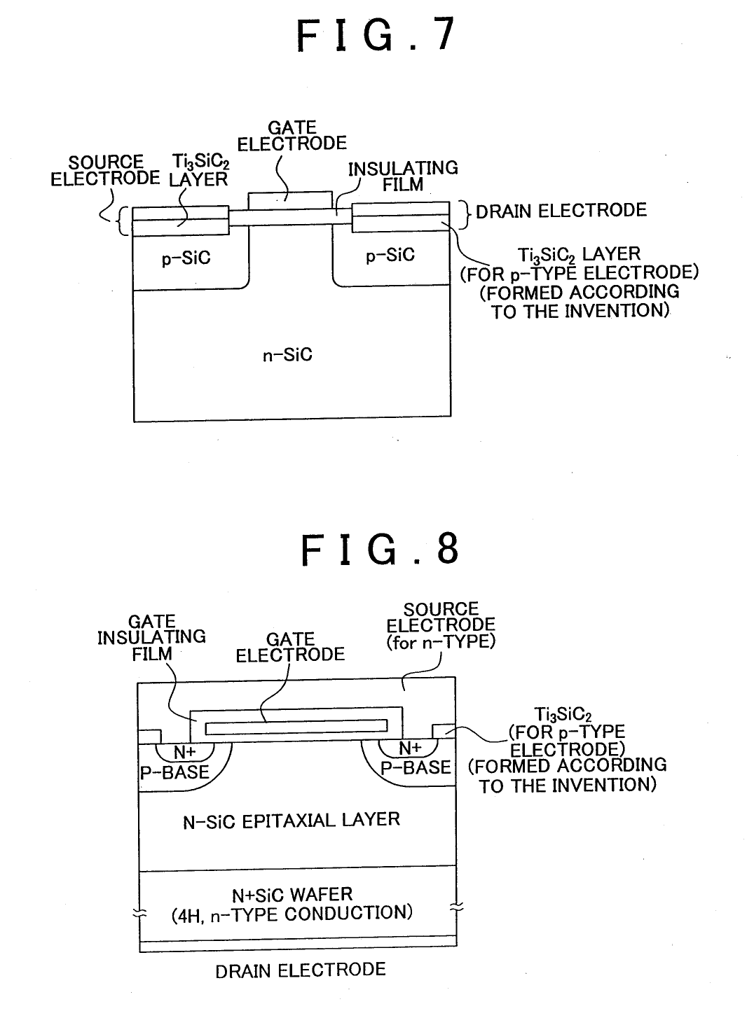

FIG. 7 is a schematic diagram showing a field-effect transistor which is made of SiC, and which is produced using the ohmic electrode of the p-type SiC semiconductor element according to the invention.

### Third Example

FIG. 8 is a schematic diagram showing an N-channel power field-effect transistor (a power MOSFET) that is produced using the ohmic electrode of the p-type SiC semiconductor element according to the invention.

### Fourth Example

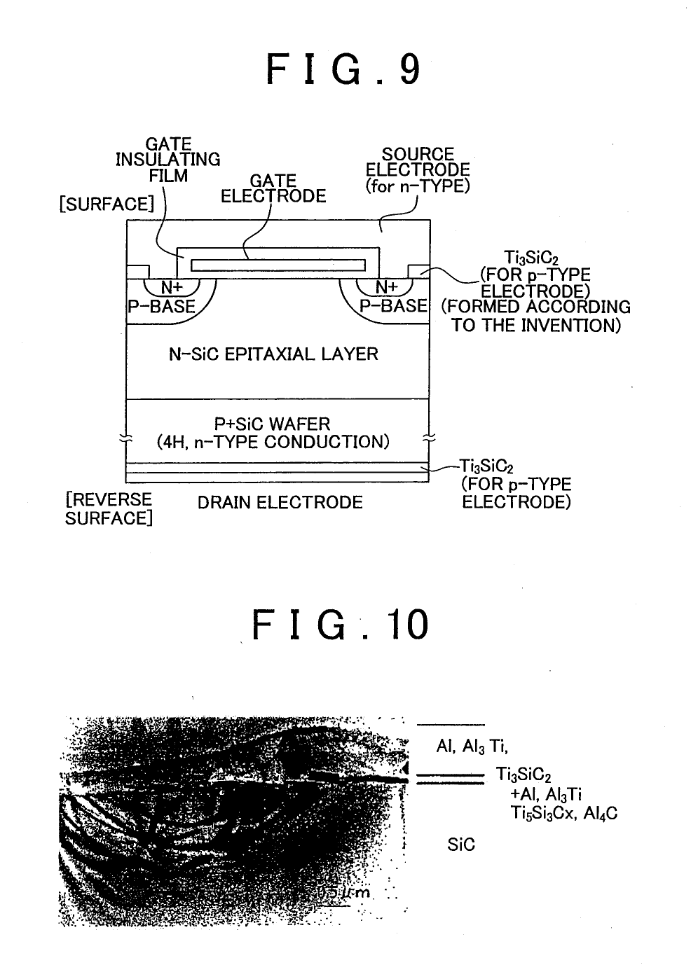

FIG. 9 is a schematic diagram showing a silicon carbide N-channel insulated gate bipolar transistor (IGBT) that is produced using the ohmic electrode of the p-type SiC semiconductor element according to the invention. The ohmic characteristic of the IGBT shown in FIG. 9 is ensured at a room temperature or a relatively low temperature. Therefore, after completion of surface processing such as formation of a gate oxide film, and ion implantation, a drain electrode is produced on a reverse surface without influence of heat.

According to the invention, it is possible to provide the ohmic electrode with high surface smoothness and a good ohmic characteristic even on the p-type SiC semiconductor, although a technology for stably forming the ohmic electrode on the p-type SiC semiconductor has not been established.

1. An ohmic electrode of a p-type SiC semiconductor element, comprising:
an ohmic electrode layer that is made of Ti₃SiC₂, and that is formed directly on a surface of a p-type SiC semiconductor.

2. The ohmic electrode according to claim 1, wherein
the ohmic electrode layer contains no Al component.

3. The ohmic electrode according to claim 1, wherein
a thickness of the ohmic electrode layer is equal to or smaller than 20 nm.

4. The ohmic electrode according to claim 3, wherein
the thickness of the ohmic electrode layer is equal to or smaller than 10 nm.

5. A method of forming an ohmic electrode of a p-type SiC semiconductor element, wherein the ohmic electrode includes an ohmic electrode layer that is made of Ti₃SiC₂, and that is formed directly on a surface of a p-type SiC semiconductor, the method comprising:
forming a ternary mixed film that includes Ti, Si, and C in a manner such that an atomic composition ratio, Ti:Si:C is 3:1:2, on a surface of a p-type SiC semiconductor to produce a laminated film; and
annealing the produced laminated film under vacuum or under an inert gas atmosphere.

6. The method according to claim 5, wherein
in forming the ternary mixed film, an evaporated ternary mixed film is formed by a deposition method after the surface of the p-type SiC semiconductor is cleaned, in vacuum deposition equipment.

7. The method according to claim 6, wherein
a thickness of the evaporated ternary mixed film is equal to or smaller than 300 nm.

8. The method according to claim 7, wherein
the thickness of the evaporated ternary mixed film is equal to or larger than 5 nm, and equal to or smaller than 300 nm.

9. The method according to any one of claims 5 to 8, wherein
in annealing the laminated film, the laminated film is annealed at a temperature which is equal to or higher than 900° C., and at which a chemical reaction proceeds while the ternary mixed film is constantly maintained in a solid phase state.

10. The method according to claim 9, wherein
the laminated film is annealed at 900° C. to 1000° C.

11. The method according to claim 10, wherein
the laminated film is annealed for 5 minutes to 120 minutes.

12. The method according to claim 11, wherein
the laminated film is annealed for 5 minutes to 30 minutes.

13. The method according to any one of claims 5 to 12, wherein
a thickness of the ohmic electrode layer is equal to or smaller than 20 nm.

14. The method according to claim 13, wherein
the thickness of the ohmic electrode layer is equal to or smaller than 10 nm.
